(19) United States
(12) Patent Application Publication
(10) Pub. No.: US 2015/0206785 A1
(43) Pub. Date: Jul. 23, 2015

(54) SUSCEPTOR, CRYSTAL GROWTH APPARATUS, AND CRYSTAL GROWTH METHOD

(71) Applicant: DOWA ELECTRONICS MATERIALS CO., LTD., Tokyo (JP)

(72) Inventors: Masahito Miyashita, Tokyo (JP); Masaaki Higo, Tokyo (JP)

(21) Appl. No.: 14/417,329

(22) PCT Filed: Jul. 26, 2013
(86) PCT No.: PCT/JP2013/070373

§ 371 Date: Jan. 26, 2015

(30) Foreign Application Priority Data
Jul. 26, 2012 (JP) 2012-165692

(51) Int. Cl. H01L 21/687; C23C 16/458; C30B 29/40; C30B 25/12

(52) U.S. Cl. CPC H01L 21/68735; C30B 25/12; C23C 16/4581; H01L 21/6875; C30B 29/403

(57) ABSTRACT

A growth layer is uniformly grown on a substrate which is mounted on a susceptor. With a lower plate of the susceptor, at the outer periphery of a substrate mounting part, an outer periphery projection part, which is higher than the substrate mounting part, is formed around the substrate mounting part. Therefore, the substrate mounting part provides a bottom face of a recessed part formed within the lower plate, the substrate being mounted in this recessed part. In other words, the lower plate is provided with such a geometry that the substrate is fitted into the recessed part surrounded by the outer periphery projection part.

### TECHNICAL FIELD

The present invention relates to a susceptor used for forming a growth layer on a substrate by the chemical vapor deposition (CVD) method, and a crystal growth apparatus and a crystal growth method which use this susceptor.

### BACKGROUND ART

Group-III nitride semiconductors, which are compound semiconductors typified by GaN, have a wide band gap, and therefore, they are widely used as materials for light-emitting devices, such as blue, green, and other color LEDs (light-emitting diodes), LDs (laser diodes), and the like, and power devices. In manufacturing semiconductor devices, such as LSIs, using silicon, and the like, a wafer having a large diameter that is obtained by cutting from a bulk crystal having a large diameter is used, while, for such Group-III nitride semiconductors, it is extremely difficult to obtain a bulk crystal having a large diameter (for example, 4-inch dia or larger). Therefore, in manufacturing a semiconductor device using such a Group-III nitride semiconductor, a wafer in which this Group-III nitride semiconductor is epitaxially grown (heteroepitaxially grown) on a substrate formed of a material dissimilar thereto is generally used.

As the epitaxial growth method for Group-III nitride semiconductors, the MBE (Molecular Beam Epitaxy) method and the MOCVD (Metal Organic Chemical Vapor Deposition) method are known. Of these, the MOCVD method is higher in mass productivity than the MBE method, and thus is preferably used. With the MOCVD method, a wafer being a substrate is mounted on a susceptor in a chamber, being held at a prescribed temperature (for example, 1000° C. or over), and an organometallic gas (material gas) containing elements constituting the raw material for the semiconductor, and the like, are caused to flow. The material gas makes a reaction on the surface of the substrate at this temperature, allowing a good quality semiconductor layer of a single crystal to be formed on the substrate.

In this case, the susceptor holding the substrate at a high temperature has a great influence on the characteristics of the grown semiconductor layer (growth layer). The susceptor is required to meet the conditions, such as (1) it has a high thermal conductivity, and can hold the temperature of the substrate constant; (2) it contains no impurity element which becomes electrically or optically active (which electrically or optically influences the characteristics) in the semiconductor; and (3) it has a sufficient mechanical strength and thermotolerance. Therefore, generally, as the material for the susceptor, graphite, which has a high thermal conductivity, or the like, is used. In addition, on the susceptor, a new substrate is mounted to perform a crystal growth after each crystal growth, however, the susceptor is repetitively used within its service life. Therefore, it is also required that, using the same susceptor, an semiconductor layer having equivalent characteristics be able to be obtained with a good reproducibility over a long period of time. Various susceptors having a structure which allows such a requirement to be met have been proposed.

In the Patent Documents 1 and 2, there is described a configuration in which, in order to improve the reproducibility for each crystal growth, a replaceable structure is newly provided on the susceptor. This structure is a cover made of SiC in the technology which is described in the Patent Document 1, while in the technology which is described in the Patent Document 2, a deposition prevention plate made of a thin graphite. Such a configuration is provided as that which allows such a structure to be appropriately replaced with a new one and washed. Thus, it is suppressed that an impurity is diffused into a susceptor from the substrate side, and the impurity is further diffused into a newly mounted another substrate or a semiconductor layer thereupon. In other words, this configuration suppresses an impurity to be transferred between substrates, and allows an semiconductor layer having good characteristics to be obtained with a good reproducibility over a long period of time.

### CITATION LIST

### Patent Literature

Patent Document 1: Japanese Patent Application Laid-open No. H 03-69113

Patent Document 2: Japanese Patent Application Laid-open No. H 06-314655

### DISCLOSURE OF THE INVENTION

### Problems to be Solved by the Invention

The above-described technology has allowed a semiconductor layer having good characteristics to be obtained with a good reproducibility, however, actually, with the semiconductor layer formed on a single substrate, the crystallinity and the film thickness have varied between the central part and the peripheral portion. In other words, the reproducibility for each growth has been good, however, the in-plane uniformity for the semiconductor layer (growth layer) has not been good.

Such a situation similarly occurs in the case where the MOCVD method or any other CVD method is used to form a growth layer on a substrate mounted on a susceptor which is temperature-controlled.

In other words, it has been difficult to uniformly grow a growth layer on a substrate mounted on a susceptor.

In addition, even outside of the substrate, i.e., even on the surfaces of the structures, such as the chamber inner wall and the susceptor, the material gas causes a reaction, thereby a reaction product (generally, a polycrystal layer having a composition similar to that of the semiconductor layer) being formed on the surfaces of the structures, such as the chamber inner wall and the susceptor. The reaction product does not always provide an impurity, however, if the reaction product is thickened, resulting in it being partially peeled off to be deposited on the substrate surface, the crystal growth is hindered in the area where the reaction product is deposited, thereby the yield being lowered. Further, with the reaction product being thickened, the surface temperature is changed, resulting in a variation in film thickness and various characteristics of the semiconductor layer on the substrate. Therefore, it is necessary that the chamber, the susceptor, and the like, be periodically replaced with a new one, and cleaned, however, it is preferable that such a maintenance operation be easy.

The present invention has been made in view of such problems, and is intended to provide a susceptor, a crystal growth apparatus, and a crystal growth method which solve the above problems.

### Means for Solving the Problems

In order to solve the above problems, the present invention is provided with the following scheme.

The susceptor of the present invention features that it is a susceptor for holding a substrate, and forming a growth layer on the substrate by the chemical vapor deposition (CVD) method,

the susceptor including a lower plate and an upper plate, being disposed on a top face of the lower plate,

the lower plate including a substrate mounting part, the substrate mounting part being an area for mounting the substrate on the top face of the lower plate, and further, including an outer periphery projection part around the substrate mounting part, the outer periphery projection part being formed so as to provide a geometry, surrounding the substrate on the substrate mounting part,

the upper plate being mounted in an area excluding the substrate mounting part and the outer periphery projection part on the top face of the lower plate, and including a geometry, exposing the substrate mounting part and a top part of the outer periphery projection part on the side of a top face of the upper plate, and

a thermal conductivity in a vertical direction of the upper plate being lower than a thermal conductivity in a vertical direction of the lower plate.

The susceptor of the present invention features that, in the substrate mounting part, the face, the substrate being mounted thereon, is set higher than the top face of the lower plate, the upper plate being mounted thereon, and is set such that, upon the lower plate being combined with the upper plate, the top face of the upper plate is flush with the top part of the outer periphery projection part.

The susceptor of the present invention features that the width of the outer periphery projection part is in the range of 1.0 mm to 5.0 mm.

The susceptor of the present invention features that the main material constituting the upper plate is pyrolithic graphite (pyrolytic carbon).

The susceptor of the present invention features that a surface protection layer is provided on the surface of the lower plate.

The susceptor of the present invention features that the surface protection layer is constituted by pyrolithic boron nitride (pBN) or silicon carbide (SiC).

The crystal growth apparatus of the present invention features that it is a crystal growth apparatus, mounting a substrate on a susceptor, and forming a growth layer on the substrate by the chemical vapor deposition method,

the susceptor comprising a lower plate and an upper plate, being disposed on a top face of the lower plate,

the lower plate including a substrate mounting part, the substrate mounting part being an area for mounting the substrate on the top face of the lower plate, and further, including an outer periphery projection part around the substrate mounting part, the outer periphery projection part being formed so as to provide a geometry, surrounding the substrate on the substrate mounting part,

the upper plate being mounted in an area excluding the substrate mounting part and the outer periphery projection part on the top face of the lower plate, and including a geometry, exposing the substrate mounting part and a top part of the outer periphery projection part on the side of a top face of the upper plate, and

a thermal conductivity in a vertical direction of the upper plate being lower than a thermal conductivity in a vertical direction of the lower plate and a thermal conductivity in a vertical direction of the substrate, respectively.

The crystal growth device of the present invention features that, in the substrate mounting part, the face, the substrate being mounted thereon, is set higher than the top face of the lower plate, the upper plate being mounted thereon, and is set such that, upon the lower plate, the substrate, and the upper plate being combined with one another, the top face of the upper plate, the top face of the substrate, and the top part of the outer periphery projection part are flush with one another.

The crystal growth apparatus of the present invention features that the width of the outer periphery projection part is in the range of 1.0 mm to 5.0 mm.

The crystal growth apparatus of the present invention features that the main material constituting the lower plate is graphite, and the main material constituting the upper plate is pyrolithic graphite (pyrolytic carbon).

The crystal growth apparatus of the present invention features that a surface protection layer is provided on the surface of the lower plate.

The crystal growth apparatus of the present invention features that the surface protection layer is constituted by pyrolithic boron nitride (pBN) or silicon carbide (SiC).

The crystal growth method of the present invention features that it is a crystal growth method, using a crystal growth apparatus, including; heating the lower plate in a chamber, and with the substrate being mounted on the susceptor and heated, causing a material gas containing a raw material for the growth layer to flow.

The crystal growth method of the present invention features that the substrate is of sapphire, and the temperature of the substrate at the time of growth of the growth layer is 1000° C. or over.

The crystal growth method of the present invention features that the growth layer is of a nitride semiconductor.

### Advantages of the Invention

The present invention is configured as above, whereby a growth layer can be uniformly grown on a substrate mounted on the susceptor. Further, the present invention can provide a susceptor which allows maintenance to be made with ease.

### BRIEF DESCRIPTION OF THE DRAWINGS

FIG. 1A and FIG. 1B are perspective views (FIG. 1A: before assembly, FIG. 1B: after assembly) of a susceptor for use in a crystal growth apparatus providing a reference example;

FIG. 2A and FIG. 2B are sectional views along a vertical direction that illustrate the way of assembling in the case where a conventional susceptor is used (FIG. 2A) and in the case where a susceptor for use in a crystal growth apparatus providing a reference example is used (FIG. 2B);

FIG. 3 is a figure schematically showing the situation of heat conduction in the conventional susceptor;

FIG. 4 is a sectional view along a vertical direction that illustrates the way of assembling in the case where a variant example of a susceptor for use in a crystal growth apparatus providing a reference example is used;

FIG. 5 is a perspective view before assembling of a susceptor for use in a crystal growth apparatus according to the embodiment of the present invention;

FIG. 6A and FIG. 6B are sectional views of the susceptor (FIG. 6A: before assembly, FIG. 6B: after assembly) for use in a crystal growth apparatus according to the embodiment of the present invention; and

FIG. 7 is an optical microscope photograph of one example of cracks which were initiated in the outer peripheral part of a growth layer.

### BEST MODE FOR CARRYING OUT THE INVENTION

Hereinbelow, a crystal growth apparatus according to an embodiment of the present invention will be explained. The inventor has found that the in-plane non-uniformity in characteristics (such as crystallinity and film thickness) of a semiconductor layer that is obtained by using the MOCVD method to grow the semiconductor layer on a substrate mounted on a susceptor is attributable to the in-plane non-uniformity in substrate temperature at the time of growth. It has been indicated that, by investigating the cause of such in-plane non-uniformity in substrate temperature, and using a susceptor having a structure which will be explained later, such non-uniformity is reduced. With such reduction, the in-plane non-uniformity in characteristics of a grown semiconductor layer is reduced. However, in this case, initiation of cracks was often found in the outermost end part of the grown semiconductor layer. With the crystal growth apparatus according to the embodiment of the present invention, there is given a further improvement about this problem.

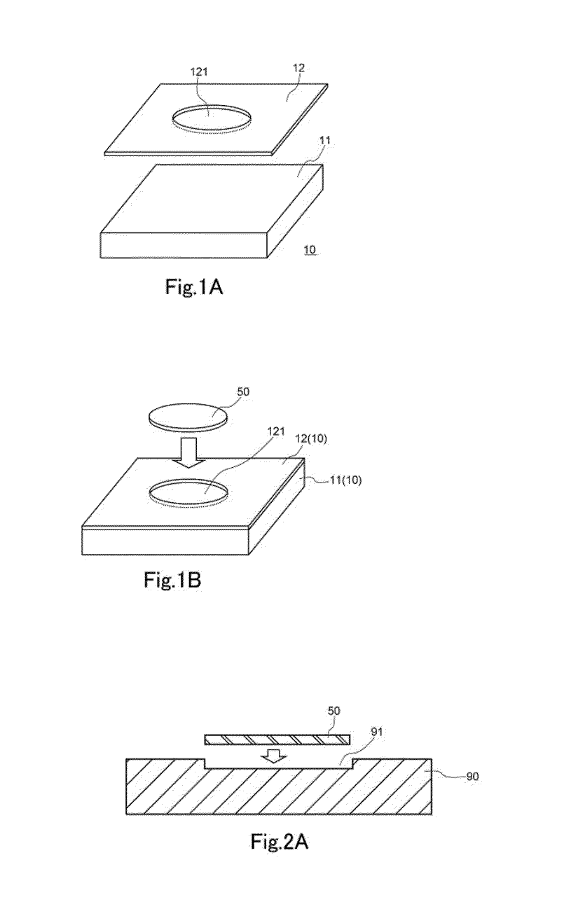

FIG. 1A and FIG. 1B are perspective views (FIG. 1A: before assembly, FIG. 1B: after assembly) of a susceptor 10, which is for use in a crystal growth apparatus providing a reference example. Here, this susceptor 10 is constituted by a lower plate 11 and an upper plate 12. With this crystal growth apparatus, a substrate is disposed on this susceptor 10 in a chamber, and in the state in which the temperature thereof is controlled, a material gas is caused to flow. With the material gas causing a chemical reaction on the surface of the substrate, a semiconductor layer is grown on the substrate. The semiconductor layer formed here is, for example, a nitride semiconductor (such as aluminum nitride), and as the substrate, a sapphire substrate is used, for example. As the material gas in this case, TMA (trymethylaluminum), NH₃ (ammonia), and the like, are used. In this case, the growth temperature is specified to be 1000° C. or over.

It is preferable that the surface (the face on which a substrate 50 is mounted) of the lower plate 11 have a geometry which minimizes the gap between it and the rear face of the substrate 50, being flat, for example. In addition, this surface is specified to be sufficiently larger than the substrate 50 used, being configured to allow the substrate (wafer) 50 substantially in the shape of a circular plate to be mounted thereon. The lower plate 11 is used to mount the substrate 50 thereon for holding it at a desired temperature, corresponding to a conventional susceptor used in a conventional crystal growth apparatus. Therefore, the material constituting the lower plate 11 is the same as that of the conventional susceptor, and for example, graphite, which has a high thermal conductivity, is used. In addition, in FIG. 1A, the lower plate 11 is drawn so as to have a rectangular geometry, however, the geometry of a portion under the surface is optional, provided that the surface has a geometry as described above. In addition, the lower plate 11 need not be constituted by a single material, and for example, a configuration in which, in order to enhance the shock resistance or chemical stability of the surface, the graphite is coated with pyrolithic boron nitride (pBN) or silicon carbide (SiC) as a surface protection layer may be used.

The lower plate 11 is configured to be heated by, for example, a heater or a heating means for high-frequency heating. In addition, the lower plate 11 is provided with a temperature sensor, the temperature measured thereby being fed back to control the heating means, whereby the lower plate 11 can be held at a prescribed temperature (for example, 1000° C. or over). The above-described lower plate can be heated from, for example, the bottom face side thereof.

On the other hand, the upper plate 12 may be thinner than the lower plate 11, the central part thereof being provided with an opening part 121. The opening part 121 is specified to have a geometry fitted to that of the substrate 50. The substrate (wafer) 50 used here may have any size, for example, two inches in diameter of a circular shape. In this case, the opening part 121 is specified to have a diameter of a circular shape that is slightly larger than two inches so as to allow the substrate 50 to be mounted therein. In addition, as shown in FIG. 1B, the upper plate 12 is used, being disposed on the surface of the lower plate 11, and thus is specified to have a geometry which is fitted to the surface of the lower plate 11. In addition, when the upper plate 12 is disposed on the surface of the lower plate 11, the surface of the lower plate 11 inside of the opening part 121 provides a substrate mounting part in which the substrate 50 is to be mounted, and thus the surface of at least this area in the lower plate 11 is specified to be flat. Thus, in the state shown in FIG. 1B, the substrate 50 is mounted in the opening part 121, and then in the state in which the temperature of this substrate 50 is held at a temperature close to that of the lower plate 11, the crystal growth can be performed. For disposing the upper plate 12 on the lower plate 11, the upper plate 12 may be removably fixed to the lower plate 11 by using such a method as tenon connection or dowel joint, which provides a recessed portion for one, and a convexed portion corresponding to it for the other, or screw-fastening the end parts thereof. In order to minimize the influence on the temperature of the substrate 50 that is given by a fixing part to be used for such fixing, it is preferable that the fixing part be provided for the lower plate 11 and the upper plate 12 in a place which is away from the substrate 50.

In FIG. 1A and FIG. 1B, the geometry of the substrate 50 is shown as a simple circular shape, however, actually, the substrate 50 is not of a complete circular shape, but in part of the circumference, an orientation flat is often provided. The geometry of the opening part 121 is set so as to allow the substrate 50 to be mounted therewithin, and may be that which is matched to the geometry of the substrate 50 having such an orientation flat.

Here, the main material constituting the upper plate 12 is different from the main material constituting the lower plate 11. Here, the main material means a material which exceeds 50% in volume ratio. Particularly, the main materials constituting these vary in thermal conductivity in a vertical direction (a thickness direction for the substrate or the upper plate 12), and the thermal conductivity of the material constituting the upper plate 12 in this direction is set to be lower than the thermal conductivity of the material constituting the lower plate 11 in the same direction. In addition, the thermal conductivity of the material constituting the upper plate 12 in the same direction is set to be lower than the thermal conductivity of the material constituting the substrate in the same direction. As the value of the thermal conductivity, that which is based on the measuring method prescribed in, for example, JIS A 1412 can be used.

For example, in the case where the lower plate 11 is constituted by graphite, the thermal conductivity thereof in a temperature zone of 1000° C. or over may be made to be 40 to 100 W/m/K or so. In addition, in the case where sapphire is used as the material of the substrate, the thermal conductivity in a thickness direction (the c-axis direction) in a temperature zone of 1000° C. or over is 8 W/m/K or so. In this case, the upper plate 12 may be constituted by, for example, pyrolithic graphite (PG: pyrolytic carbon). The constitutional element of PG is carbon as with general graphite, however, PG is prepared by using the CVD to form a thick film with a thickness of a few mm or so on the base material comprised of graphite, thereby having a high anisotropy, and the thermal conductivity in the in-plane direction is greatly different from that in the thickness direction. Therefore, if the upper plate 12 in the shape of a thin plate is formed of PG, the thermal conductivity in the thickness direction thereof can be made to be, for example, 1.5 W/m/K or so in the temperature zone of 1000° C. or over. With such a material constitution, the relationship of magnitude among the above-mentioned thermal conductivities is satisfied. Generally, although graphite will react with ammonia gas at a high temperature, being eroded, PG, which is formed dense, has a low reactivity with ammonia gas, and thus can withstand a long-term use. It is particularly preferable to use such a PG, being resistant to ammonia.

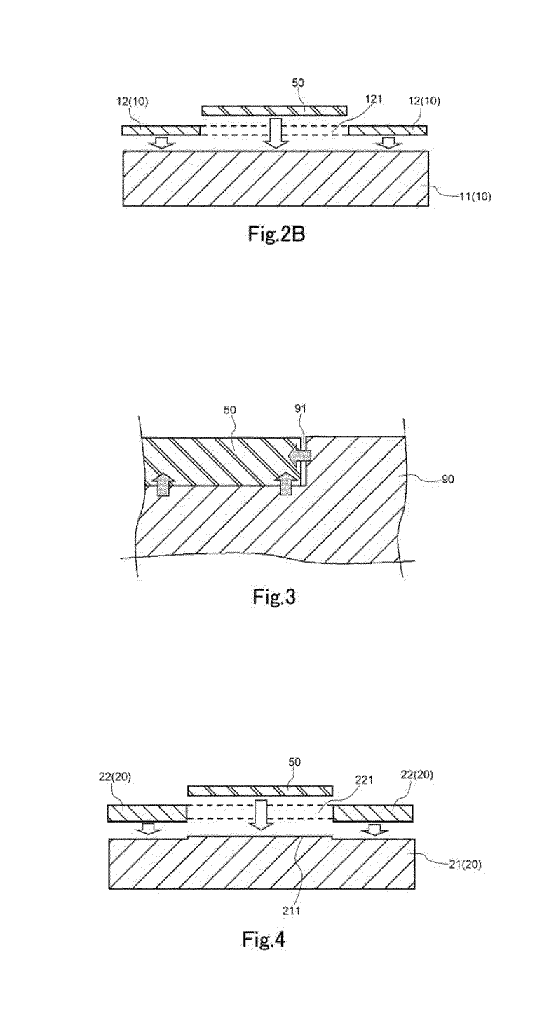

FIG. 2A and FIG. 2B are sectional views along the thickness direction (a vertical direction) of the substrate that illustrate the way of assembling in the case where a conventional susceptor 90 is used (FIG. 2A) and in the case where the above-described susceptor 10 is used (FIG. 2B). The conventional susceptor 90 is specified to be a solid part, however, in order to fix the substrate 50 thereon, a recessed part 91 corresponding to the geometry of the substrate 50 is formed on the surface thereof. The bottom face of the recessed part 91 is specified to be flat. Here, the thickness of the substrate 50 is, for example, 430 μm or so, while the depth of the recessed part 91 is 0.5 mm or so, and the geometry thereof is specified to be a geometry which can hold the substrate 50 therein, for example, a circular geometry having a diameter slightly over two inches in the case where the substrate 50 having a 2-inch diameter is used. The sectional geometry of the recessed part 91 may be any geometry, provided that the material gas can be smoothly supplied to or discharged from the surface of the substrate 50. In the above-described configuration, the surface of the mounted substrate 50 is substantially flush with the surface of the susceptor 90 surrounding it, which is a preferable matter.

Contrarily to this, with the above-described susceptor 10, the substrate 50 is fixed, being held in the opening part 121 (substrate mounting part) of the upper plate 12. In other words, with the above-described susceptor 10, the lower plate 11 corresponds to the conventional susceptor 90 having no recessed part 91, and the opening part 121 of the upper plate 12 corresponds to the recessed part 91. Therefore, in the case where the thickness of the substrate 50 is 430 μm or so, the thickness of the upper plate 12 may be specified to be, for example, 0.5 mm or so, which is equivalent to the above-described depth of the recessed part 91, and the opening part 121 may be specified to be of a circular geometry having a diameter slightly over two inches.

Here is a discussion about the fact that, by using the susceptor 10 configured as above, the non-uniformity in substrate temperature is eliminated.

Using the conventional susceptor 90 shown in FIG. 2A, the inventor grew a semiconductor layer on the substrates (wafers) 50 having two different sizes (2-inch dia and 4-inch dia), and investigated the electrical characteristics and the crystallinity of the semiconductor layer formed. The results indicated that, in either case, the characteristics (crystallinity and film thickness) varied between the central part and the peripheral portion of the semiconductor layer. However, the result of a detailed investigation of the characteristics of the semiconductor layer obtained with the 4-inch dia wafer indicated that the characteristics in the area in the central part of the 4-inch dia wafer that corresponds to the 2-inch dia wafer are substantially uniformly equivalent to those of the central part, which is greatly different from the result of an investigation of the 2-inch dia wafer. In addition, as a result of using a radiation thermometer to measure the temperature in a non-contact manner, it has been confirmed that the temperature of the surface of the substrate 50 mounted on the susceptor 90 is lower than the temperature of the surface of the susceptor therearound by 50° C. to 100° C. or so, although strictly speaking the temperature of the surface of the substrate 50 varies depending upon the conditions, such as the growth temperature and the pressure.

This fact can be associated with the fact that the above-mentioned in-plane non-uniformity was not caused over the entire face of the substrate, but was caused only in the end part thereof regardless of the size of the substrate. In other words, from the results of the above-described temperature measurement, it can be said that the above-mentioned in-plane non-uniformity was caused by that, around the substrate, there occurred an area where the temperature was raised. Therefore, it can be considered that, by using a susceptor having a structure with which occurrence of an area causing a non-uniformity in substrate temperature is difficult, the in-plane non-uniformity will be reduced.

FIG. 3 schematically shows the situation of heat conduction from the susceptor 90 to the substrate 50 in the conventional configuration in FIG. 2A. Here, the section of the area including the end part of the recessed part 91 in a situation in which the substrate 50 is mounted is shown, being enlarged, and the arrows in the figure indicate the direction of heat conduction. First, it is obvious that, in the central part of the substrate 50 (the area which is away from the end part of the recessed part 91), heat conduction in a vertical direction toward the upper side from the surface of the susceptor 90 is predominant. However, for the end part of the substrate 50, it is necessary to consider two types of heat conduction, i.e., the heat conduction in such vertical direction, and the heat conduction in a lateral direction from the end part of the recessed part 91 in the susceptor 90. The heat conduction in this lateral direction is heat conduction which is directed toward the substrate 50 from the wall face of the recessed part 91 that is opposed to the end face of the substrate 50. Actually, although the substrate 50 is heated not only by heat conduction, but also radiation from the susceptor 90, the influence thereof is the same.

Here, although there is provided a state of face contact between the substrate 50 and the susceptor 90 on the susceptor 90, the mounted substrate 50 is fixed by only the gravity. Therefore, although both of the rear face of the substrate 50 and the surface of the susceptor 90 are flat, the degree of adhesion between these is low, the thermal resistance between the substrate 50 and the susceptor 90 being not small. Therefore, although it is preferable that the heat conduction in a vertical direction be predominant as described above, the efficiency of such heat conduction in a vertical direction is actually not high, even if the susceptor 90 and the substrate 50 both have a high thermal conductivity in the thickness direction.

In addition, in the case where the growth temperature is, for example, 800° C. or over, between the substrate 50 and the susceptor 90, there exists a situation of heat conduction that the influence of heating by radiation from the susceptor 90 is stronger than that of heat conduction by contact. Further, in the case where the growth temperature is 1000° C. or over, as with the case where a Group-III nitride semiconductor is grown, the radiation is predominant. This is because the heat conduction is determined in proportion to the difference in temperature between the two substances (the substrate 50 and the susceptor 90), while the release of energy by radiation is in proportion to the fourth power of the temperature of the heat source (the susceptor 90). Therefore, in FIG. 3, the influence of heat conduction or radiation from the lateral direction in the end part of the substrate 50 cannot be neglected.

Therefore, it can be considered that, in the case where the temperature of the susceptor just under the substrate is a certain constant temperature, if the temperature of the susceptor surface around the substrate (i.e., in the area where the substrate is not mounted) can be made the same as or lower than the substrate surface temperature, the non-uniformity in temperature of the substrate end part will be reduced. Since the temperature of the surface of the substrate directly influences the crystal growth, the temperature of the susceptor can be set at a temperature higher than a desired temperature of the surface of the substrate such that the temperature of the surface of the substrate is a desired one.

Then, with the above-described susceptor 10, as the portion corresponding to the conventional susceptor 90, the lower plate 11 is used. In order to fix the substrate 50, the upper plate 12, which is a member independent of the lower plate 11, is used. However, in avoidance of that, in the state in which the substrate 50 is mounted on the lower plate 11, a part of the lower plate 11, which has a higher temperature, is opposed to the side face of the substrate 50, there is not provided a recessed part, unlike the conventional susceptor 90. In other words, the surface of the lower plate 11 is made flat, unlike the susceptor 90. Instead, the wall face of the opening part 121 of the upper plate 12 is opposed to the side face of the substrate 50.

The upper plate 12 is in the state in which it is mounted on the lower plate 11 by the gravity, as with the substrate 50. Therefore, as with between the substrate 50 and the lower plate 11, the thermal resistance between the upper plate 12 and the lower plate 11 is also high. Further, because the thermal conductivity of the upper plate 12 is set to be lower than that of the lower plate 11 and that of the substrate 50, the efficiency of heat conduction to the upper plate 12 is still lower than the efficiency of heat conduction to the substrate 50, whereby the temperature of the surface of the upper plate 12 can be lowered. In addition, the temperature of the wall face of the opening part 121 that is opposed to the side face of the substrate 50 is lower than the temperature of the wall face of the recessed part 91 in the conventional susceptor 90. Therefore, the influence of the heat conduction or radiation in the lateral direction from the upper plate 12 on the substrate 50 in the configuration in FIG. 2B is smaller than the influence of the heat conduction or radiation in the lateral direction from the end part of the recessed part 91 of the susceptor 90 on the substrate 50 in the configuration in FIG. 2A and FIG. 3. Therefore, as compared to the conventional configuration in FIG. 2A, the non-uniformity in temperature of the end part of the substrate 50 can be reduced. In addition, due to the above-described temperature dependency of the heating by heat conduction and radiation, in the case where the growth temperature is 1000° C. or over, a particularly high effect can be obtained.

In addition, it is obvious that, by using the upper plate 12, which is independent of the lower plate 11, the same advantages as those stated in the Patent Documents 1 and 2 can be obtained. In other words, with this configuration, the upper plate 12, which provides the outermost surface, is easier to be contaminated than the lower plate 11, however, upon being contaminated, replacement with a new one, cleaning, and the like, of the upper plate 12 can be easily performed, whereby crystal growth can be performed with a high reproducibility. In addition, if the surface temperature of the upper plate 12 is lowered, the chemical reaction on the surface thereof is generally more difficult to be caused. Therefore, as compared to the conventional susceptor 90, the amount of a reaction product which is deposited on the surface of the upper plate 12 is reduced.

In addition, this susceptor 10 is disposed in a chamber, and in this chamber, a semiconductor layer is formed on the substrate 50. In this case, the chamber inner wall is also heated by the radiation from the susceptor and the substrate which are faced thereto, and thus also on the chamber inner wall, the reaction product is deposited. Therefore, generally it is required that, for the chamber on which the reaction product has been deposited, a maintenance operation, such as replacement with a new one or cleaning, be made at an appropriate frequency. Contrarily to this, in the case where the above-described susceptor 10 is used, the surface temperature of the upper plate 12 is lowered, thereby the temperature of the chamber inner wall which is opposed thereto is also lowered. Therefore, the amount of the reaction product which is deposited on the chamber inner wall is also reduced.

In other words, in the case where this susceptor 10 is used, the amount of the reaction product which is deposited on the susceptor 10 or the chamber can also be reduced, whereby the frequency of maintenance can be lowered, and replacement with a new one or cleaning of the upper plate 12 on which the reaction product has been deposited can be easily performed.

The upper plate 12 may be constituted by a material which makes this cleaning particularly easy. For example, in the case where the reaction product is, for example, AlInGaN, which has a coefficient of thermal expansion of 4 to 6 ppm/K or so, using the above-described PG, which has a coefficient of thermal expansion of 1 ppm/K or so, as the material of the upper plate 12 will make it particularly easy to peel off the reaction product or cleaning, due to the difference in coefficient of thermal expansion.

In addition, since, for the lower plate 11, a material which is high in thermal conductivity is selected and used, and therefore the material of the substrate 50 generally has a thermal conductivity lower than the thermal conductivity of the lower plate 11. As the material for the upper plate 12, according to the material of the substrate 50, a material having a thermal conductivity lower than that of the material of the substrate 50 may be appropriately selected. For example, SiC (with a thermal conductivity of 70 W/m/K or so in the temperature zone of 1000° C. or over) and TaC (with a thermal conductivity of 9 to 22 W/m/K or so in the temperature zone of 1000° C. or over) have a thermal conductivity higher than that of the above-described sapphire, however, these may be used when a material which is higher in thermal conductivity than these is used as that of the substrate 50.

It is required that the upper plate 12 be constituted by a material which will not react with or has a low reactivity with the gas used (such as ammonia or hydrogen). In this point, any of the above-mentioned materials can be used with no problem. This is also true for the lower plate 11.

FIG. 4 is a sectional view illustrating the way of assembling a susceptor 20, which is a variant example of the above-described susceptor 10, providing a reference example. With this susceptor 20, a lower plate 21 and an upper plate 22 are used, the heat conduction to the upper plate 22 being further suppressed. Here, the materials constituting the lower plate 21 and the upper plate 22 are the same as those of the above-described lower plate 11 and upper plate 12, respectively, and only the geometries thereof differ.

With the lower plate 21, contrarily to the conventional susceptor 90 shown in FIG. 2A, a substrate mounting part 211, which provides an area for the substrate 50 to be mounted thereon, is made higher than the surrounding thereof. Or, the surface of the lower plate 21 excluding the substrate mounting part 211 is provided as that which is digged down below the substrate mounting part 211. The surface of the substrate mounting part 211 is specified to be flat as with the surface of the above-described lower plate 11.

In the upper plate 22, an opening part 221, which is matched to the substrate 50 is formed as with the above-described upper plate 12. In addition, in this case, the opening part 221 is set so as to correspond to the substrate mounting part 211 when the upper plate 22 is combined with the lower plate 21. In other words, when this susceptor 20 is used, the substrate 50 is loaded on the substrate mounting part 211 in the opening part 221.

On the other hand, the area excluding the substrate mounting part 211 in the lower plate 21 is provided with a geometry which is digged down from the substrate mounting part 211. Therefore, in the case where, in the state in which the upper plate 22 is combined with the lower plate 21, the top face of the upper plate 22 is to be flush with the top face of the substrate 50 as with the above-described susceptor 10, the thickness of the upper plate 22 may be made equal to the depth by which the surface of the lower plate 21 has been digged down.

In other words, as compared to the above-described susceptor 10, the upper plate 22 may be thickened. Since the upper plate 22, which has a low thermal conductivity, is thickened, the temperature of the surface of the upper plate 22 can be further lowered. Therefore, the non-uniformity in temperature in the end part of the substrate 50 can be further reduced.

In addition, with this susceptor 20, since the convexed part of the lower plate 21 (the substrate mounting part 211) is fitted to the opening part 221 of the upper plate 22, disposition and fixing of the upper plate 22 on/to the lower plate 21 is more positively performed.

In either of the above-described cases illustrated in FIG. 2B and FIG. 4, in order to make the temperature of the surface of the upper plate 22 (12) the same as or lower than the temperature of the surface of the substrate 50, it is required that the following relationship be met, assuming that the thickness of the substrate 50 is Ts; the thermal conductivity thereof is λ_{S}; the thickness of the upper plate 22 (12) is T_{TP}; and the thermal conductivity thereof is XTP.

[Math 1]

T_{TP}/λ_{TP}≧T_{S}/λ_{S} (1)

Actually, the thickness of the substrate which is normally used is 500 μm or so, the upper limit of the thickness T_{TP} of the upper plate 22 (12) is specified to be, for example, 2000 μm or so. In addition, since the upper plate 12, 22 is required to be handled as a thin plate member independent of the lower plate 11, 21, the lower limit of thickness of the upper plate 12, 22 means the lower limit of thickness that allows the pertinent material to be manufactured as a portable thin plate, which is, for example, 200 μm or so for PG. The value of T_{TP} is set in consideration of the expression (1), however, in the case where the thickness of the entire susceptor 10, 20 (the total thickness when the upper plate 12, 22 is mounted on the lower plate 11, 21) is set, the value of T_{TP} is set also depending upon the thickness of the lower plate 11, 21. However, the thicker the upper plate 12, 22, the more the camber thereof will be suppressed.

However, so long as supply of the material gas to the substrate surface is performed uniformly within the plane, the top face of the substrate need not be strictly flush with the top face of the upper plate. If the top face of the upper plate is higher than the top face of the substrate, the temperature of the top face of the upper plate can be further lowered. In addition, even if the top face of the upper plate is lower than the top face of the substrate, it is obvious that the temperature of the top face of the upper plate can be lowered as compared to the conventional susceptor.

### Embodiment of the Present Invention

With the above-described susceptor, which provides a reference example, by adjusting the temperature distribution of the top face of the susceptor including the wafer, and particularly lowering the temperature of the top face of the upper plate, the in-plane uniformity of the growth layer on the substrate has been improved as described above. However, in the case where the susceptor of this configuration was used, initiation of cracks was often found in the outermost end part (outer peripheral part) of the growth layer. It can be considered that this is because the above-described configuration allows the temperature distribution in most of the area of the growth layer to be made uniform, while having increased the temperature gradient in the outer peripheral part (the outermost end part) of the growth layer, on the contrary. In other words, it can be considered that the above-described configuration eliminated the area having a large temperature gradient in a wide range on the substrate, but, in a narrow area close to the outermost end part on the substrate, formed an area having a large temperature gradient. Then, for the susceptor of the embodiment of the present invention, in order to solve such problem, there has been provided a configuration which assures a uniform growth layer, while decreasing the temperature gradient in the outer peripheral part of the substrate.

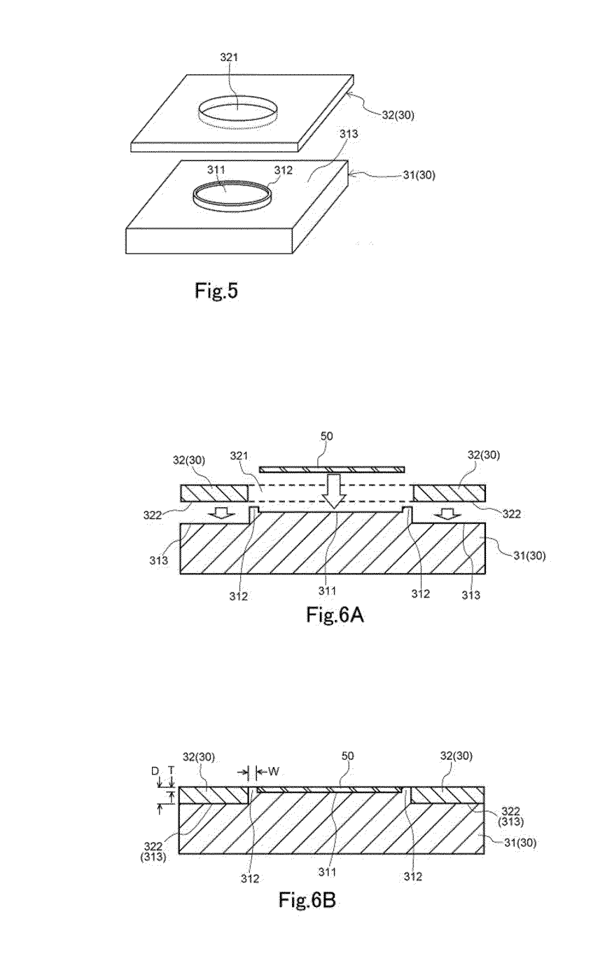

FIG. 5 is a perspective view before assembling of a lower plate 31, an upper plate 32, and a substrate 50 in a susceptor 30 according to the embodiment of the present invention, and FIG. 6A and FIG. 6B are sectional views before assembly (FIG. 6A), and after assembly (FIG. 6B) along the thickness direction of the substrate 50. Here, with the upper plate 32, a circular opening part 321 is formed as with the upper plate 22 in FIG. 4, and a substrate mounting part 311 in the lower plate 31 is also set higher than the face on which the upper plate 32 is to be mounted. The thermal conductivity of the lower plate 31 and that of the upper plate 32 are set in the same manner as in the above-described reference example. Therefore, the temperature uniformity in most of the area on the substrate 50 can be enhanced, and thus the uniformity of the growth layer can be enhanced as in the above-described reference example.

However, with this lower plate 31, an outer periphery projection part 312, which is higher than the outer periphery of the substrate mounting part 311, is formed around the substrate mounting part 311. Therefore, the substrate mounting part 311 is provided as a bottom face of the recessed part which is formed in the lower plate 31, and the substrate 50 is mounted in this recessed part. In other words, the lower plate 31 is provided with such a geometry that the substrate 50 is fitted into the recessed part surrounded by the outer periphery projection part 312. On the other hand, the opening part 321 of the upper plate 32 is specified to have a geometry which corresponds to the outside diameter of the outer periphery projection part 312 rather than that of the substrate 50, thereby fitting to the outer periphery projection part 312. The top part of the outer periphery projection part 312 is specified to provide a surface which is parallel with the surfaces of the substrate mounting part 311, and the like.

With this configuration, a lower plate top face 313 (a top face of the lower plate 31) outside of the outer periphery projection part 312 may be, for example, of a flat geometry. In addition, when the substrate 50 and the upper plate 32 are disposed on the lower plate 31, the lower plate top face 313 is brought into contact with an upper plate bottom face 322 (a bottom face of the upper plate 32). Although the lower plate top face 313 and the upper plate bottom face 322 which are brought into contact with each other may be both provided with, for example, a flat geometry, they need not be of a flat geometry, if the material gas is difficult to enter into an interface produced when they are contacted with each other. In this case, when viewed from the top side, the top face of the substrate 50 and the top part of the outer periphery projection part 312 are exposed from the upper plate 32. The figure shown as an example indicates that, between the inner periphery of the upper plate 32 that constitutes the opening part 321 and the outer periphery of the substrate 50, the outer periphery projection part 312, which is integrated with the lower plate 31, is provided, while, in the above-described reference example, the inner periphery of the upper plate 12 that constitutes the opening part 121 is directly faced to the outer periphery of the substrate 50 when viewed from the top face.

In addition, the depth T of the above-described recessed part (the height of the outer periphery projection part 312 from the substrate mounting part 311) in FIG. 6A and FIG. 6B is specified to be the same as the thickness of the substrate 50 (for example, 0.43 mm or so). The thickness D of the upper plate 32 is specified to be the same as the height of the outside wall of the outer periphery projection part 312 of the lower plate 31, i.e., the height of the outer periphery projection part 312 from the face on which the upper plate 32 is mounted. In order to make the substrate mounting part 311 higher than the face on which the upper plate 32 is mounted in the same manner as described above, the thickness D may be thicker than that of the substrate 50, i.e., 2 mm or so. With this configuration, as shown in FIG. 6B, in the state after assembly, the top faces of the upper plate 32 and the substrate 50 become flush with each other on the lower plate 31. In addition, the substrate 50 is not supported by the upper plate 32, but supported only by the lower plate 31.

In addition, the materials constituting the lower plate 31 and the upper plate 32, and the thermal conductivities thereof are specified to be the same as those in the reference example. In other words, for example, the lower plate 31 may be constituted by graphite coated with a thin PG film, and the upper plate may be constituted by PG.

This configuration has the same features as those described in the above-described reference example, except that there exists the outer periphery projection part 312, and therefore, it is obvious that the same advantages as those described in the above-described reference example are provided. Therefore, at the time of crystal growth, on the top face side, the temperature of the surface of the upper plate 32 around the substrate 50 can be lowered, whereby the uniformity of a growth layer grown on the substrate 50 can be enhanced.

Here, although the outer periphery projection part 312 is a part of the lower plate 31, the outer periphery projection part 312 takes a form which is locally protruded upward, and therefore, the temperature of the outer periphery projection part 312 will not be equal to the temperature of the main body of the lower plate 31, which is located under the outer periphery projection part 312, being lower than the temperature of the main body.

The temperature of the outer periphery projection part 312 will depend upon the temperatures of the main body of the lower plate 31, which is located under the the outer periphery projection part 312, the upper plate 32, and the substrate 50. Therefore, the area having a large temperature gradient in the outer peripheral part of the growth layer that was formed in the case where the susceptor of the reference example was used will be formed in this outer periphery projection part 312. Since the area which has a large temperature gradient is not formed within the substrate 50, initiation of a crack in the outer peripheral part of the growth layer is suppressed.

In addition, the width W of the outer periphery projection part 312 along a right-left direction in FIG. 6A and FIG. 6B is preferably 1 to 5 mm, and more preferably 1 to 3 mm. If this width W is under 1.0 mm, the effect which minimizes the temperature gradient in the area of the outermost periphery of the substrate 50 will be reduced. If this width W exceeds 5 mm, the susceptor 30 substantially approaches the conventional susceptor 90 (FIG. 2A), thereby the uniformity of the growth layer will be lowered.

In addition, as described above, in order to make the supply of the material gas to the substrate 50 smooth, it is preferable that the top face of the substrate 50 and the top face of the upper plate 32 be flush with each other, however, here, it is preferable that the top face of the outer periphery projection part 312 be also flush with these. Here, the outer periphery projection part 312 is made still higher than the substrate mounting part 311, and therefore the upper plate 32 may be made thicker than that of the reference example.

As described above, because the top face of the upper plate 32 is exposed to the material gas at the time of growth, a reaction product layer is formed on the top face of the upper plate 32. Being attributable to the difference in coefficient of thermal expansion between the reaction product layer and the upper plate 32, there may occur a camber in the upper plate 32 at the time of heating (at the time of growth), and in this case, such a problem as that the reproducibility of the temperature distribution is deteriorated is presented. In order to suppress this, it is effective to sufficiently thicken the upper plate 32. With the above-described configuration, even if the substrate 50 is thin, the upper plate 32, which is sufficiently thickened, may be used. In other words, with such susceptor 30, the upper plate 32, with which occurrence of a camber is suppressed because of the thickness, may be used. Thus, the reproducibility of a crystal growth can be enhanced.

In the above-described embodiment, a case where one substrate is mounted on one susceptor has been described, however, actually, a plurality of substrates may be appropriately disposed. In this case, the opening part of the upper plate, the substrate mounting part of the lower plate, and the like, can be formed in accordance with the configuration in which the plurality of substrates are disposed. Even in such a case, it is obvious that the above-described configuration allows a high uniformity in temperature to be obtained in the individual substrates, whereby a semiconductor layer which has a high in-plane uniformity can be obtained. Especially in the case where a plurality of substrates are mounted on the susceptor, in order to enhance the uniformity between substrates, the susceptor and the individual substrates may be rotated, however, it is obvious that, even in such case, the same advantages are provided.

However, in the case where a plurality of substrates are disposed, the configuration of the susceptor in the area between substrates may be appropriately set. For example, in the case where the spacing between substrates is narrow (in the case where the closest spacing between substrates is 0 to 5 mm), a substrate mounting part which integrates the substrate mounting parts corresponding to the adjacent two substrates may be considered as the above-described substrate mounting part. In this case, the opening parts 321 corresponding to the adjacent two substrates may be made continuous to provide a form in which, between the two substrates, the upper plate does not exist. Or, in the case where the closest spacing between substrates is as particularly narrow as under 1 mm, there may be provided a configuration in which, between the substrates, the outer periphery projection part is also not provided, and only around the integrated substrate mounting part, the outer periphery projection part is provided. The above statement is also applicable to the case where three or more substrates are used. In other words, even in such a case, in the state in which the upper plate is disposed on the top face of the lower plate, the top face of the lower plate and the bottom face of the upper plate are in face contact with each other in the area excluding the substrate mounting part and outer periphery projection part. In addition, in this case, the upper plate is specified to have such a geometry that the top face of the mounted substrate and the top part of the outer periphery projection part are exposed on the top face of the upper plate.

Such a configuration is effective in the case where, for example, a number of substrates (wafers) having a relatively small diameter of 2 to 3 inches are disposed. In such a case, as compared to the case where a large diameter substrate is disposed, the area where the susceptor (the lower plate) is exposed is small, and therefore, the effect provided by the configuration around the substrate in the susceptor according to the reference example or the above-described embodiment is relatively small. Contrarily to this, in the case where a plurality of substrates having a diameter over 3 inches are disposed, the area where the lower plate is exposed is increased. Therefore, the effect provided by the configuration around the substrate in the susceptor according to the reference example or the above-described embodiment is enhanced. In other words, the susceptor of the present invention is particularly effective in the case where a plurality of substrates having a large diameter are arranged.

In the above-described embodiment, it is preferable that the upper plate be uniformly constituted by a single material, such as PG, however, this is not always required, but the upper plate may be constituted by a composite material, such as that with which a surface protection layer is formed thick on a base material, provided that the requirement that the thermal conductivity in a vertical direction of the main material constituting the upper plate be lower than that of the substrate or the lower plate is met. For example, the upper plate may be constituted by using graphite as a base material, and coating it with PG, which is low in thermal conductivity, thick (so thick that the PG provides the main material). In addition, PG may be used as a base material, and it may be coated with pBN (thermal conductivity: 2.7 W/m/K or so), which is soft as a single substance, thereby being difficult to constitute the upper plate. Even in such a case, the surface temperature of the upper plate can be made lower than the surface temperature of the substrate, whereby the same advantages can be provided. However, in such a case, there occur a peeling and a crack which are attributable to the difference in coefficient of thermal expansion between the base material and the coating layer, and a deterioration in durability due to these; therefore it is generally preferable that the upper plate be constituted by a single material, and as the material in this case, PG is particularly preferable.

### EXAMPLES

Actually, on respective two different forms of susceptors shown in FIG. 2A and FIG. 2B, (FIG. 2A: comparative example, FIG. 2B: reference example), a sapphire substrate is mounted; the respective susceptors are disposed in a chamber, and in the chamber, the material gas and the carrier gas (N₂ and H₂) are caused to flow from the lateral direction onto the substrate, while using a a heater under the susceptor to heat the susceptor, for performing a crystal growth of AlN on the sapphire substrate under the same conditions except for the susceptors. As the substrate, a 2-inch-dia and 430-μm-thick sapphire substrate (having a thermal conductivity in a vertical direction at a temperature zone of 1000° C. or over of approx. 8 W/m/K) was used, and as the material gas, TMA and NH₃ were used.

The material of the susceptor of the comparative example was 6.5-mm-thick graphite (having a thermal conductivity in a vertical direction at a temperature zone of 1000° C. or over of 40 to 100 W/m/K), being coated with 150-μm pBN on the surface. The depth of the recessed part was 0.5 mm. The lower plate of the reference example was a 6-mm-thick flat plate structure, the material thereof being the same as that of the susceptor of the comparative example. The material of the upper plate of the reference example was PG (having a thermal conductivity in a vertical direction at a temperature zone of 1000° C. or over of approx. 1.5 W/m/K), being 0.5-mm thick.

The measurement results about the semiconductor layer that were obtained using the susceptors of the comparative example and the reference example are given under the headings of comparative example 1 and reference example 1 in Table 1, respectively. The growth temperature (the actual temperature of the substrate surface that is measured in non-contact) was specified to be 1150° C. Here, at 25 places in total including the central point within the 2-inch dia face, the film thickness distribution of the semiconductor layer was measured, and as the uniformity, the film thickness distribution was calculated using the following expression.

[Math 2]

Film thickness distribution(%)=(maximum value−minimum value)/(maximum value+minimum value)×100 (2)

In addition, as the amount which indicates the crystallinity, at the center of full width at half maximum (FWHM) (arcsec) of the X-ray diffraction rocking curve (XRC) for the (002) plane of the semiconductor layer (AlN) and four points 20 mm away from the center, i.e., at five points in total, the difference between the maximum value and the minimum value of measurement (ΔXRC (002)) was determined, and for the (102) plane, the difference between the maximum value and the minimum value of measurement (ΔXRC (102)) was determined in the same manner.

TABLE 1

| | | Comparative | Reference |
|---|---|---|---|
| | | example 1 | example 1 |
| Growth temperature (° C.) | | 1150 | 1150 |
| Film thickness | Center | 653.9 | 660.7 |
| (nm) | Average | 669.9 | 658.9 |

| | | |
|---|---|---|
| Film thickness distribution (%) | 1.1 | 0.41 |
| Standardized growth speed | 1 | 0.9837 |
| ΔXRC (002) (arcsec) | 16 | 8 |
| ΔXRC (102) (arcsec) | 669 | 40 |

From these results, it can be confirmed that, although there was no significant difference in average growth rate between the comparative example 1 and the reference example 1, the film thickness distribution for the reference example 1 was decreased. In addition, also for the crystallinity, it can be confirmed that ΔXRC (002) and ΔXRC (102) for the reference example 1 were both small, a high uniformity having been given. The minimum value of FWHM for the (002) plane of the reference example 1 was 55 arcsec, while the minimum value of FWHM for the (102) plane thereof was 1030 arcsec.

In addition, with the susceptor of the comparative example, in order to remove the AlN deposited on the susceptor, it was required to immerse the susceptor in an alkaline solution, and cleaning thereof for reuse was not easy. Contrarily to this, with the susceptor of the reference example, the AlN deposited on the upper plate could be removed simply by rubbing it with a light force, using a wiper, or the like, and cleaning the susceptor was easy.

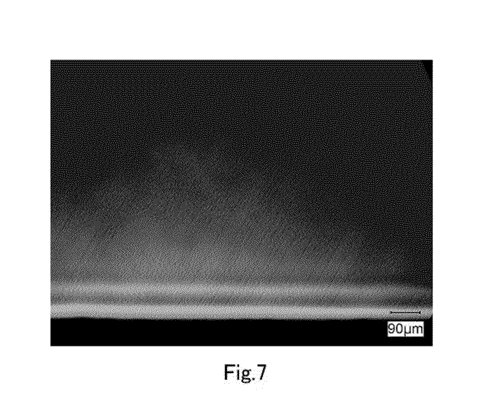

Next, using the susceptor of the reference example as the reference example 2, an AlN layer having a thickness of 1.0 μm was grown on a sapphire substrate in the same manner as that with the reference example 1, except that the growth temperature was set at 1300° C., and the pressure was at 10 Torr. As a result of this, although a growth layer (AlN layer) having a high uniformity was obtained as with the reference example 1, cracks were initiated in the outer periphery end part thereof. FIG. 7 shows an optical microscope photograph of the surface thereof. In FIG. 7, the grey area represents the growth layer, and the boundary line between this area and the black area provides an end part of the growth layer. The photo indicates a number of cracks which run from the lower left side to the upper right side. Actually, these cracks are formed only in an extremely narrow area of the end part, and the device is formed in a place away from this area toward the central part of the wafer, thereby the cracks having no great influence on the device, however, a crack in the end part may propagate, resulting in a breakage of the substrate, and therefore it is more preferable to suppress occurrence of such cracks.

Then, using the susceptor of Example, as Example 1, that has the same material as that for the reference example (the lower plate being of graphite coated with pBN, and the upper plate being of PG), and is configured to have a geometry of T=0.5 mm, D=2 mm, and W=2 mm in FIG. 6B, a crystal growth was performed under the same growing conditions as those for the reference example 2. The thickness of the entire susceptor of Example was 6.5 mm as with the susceptors of the comparative example and the reference example. Under the same conditions, crystal growth was performed five times, and it was found that, with the reference example 2, which used the susceptor of the reference example, cracks were initiated in the end part, every time crystal growth was performed, while, with Example 1, which used the susceptor of Example, no such cracks were initiated. In other words, it could be confirmed that, in order to avoid occurrence of such cracks, the susceptor of Example is effective.

In addition, in the case where the susceptor of Example was used, the warpage of the upper plate after the crystal growth of the upper plate or during the camber thereof was reduced. With the reference example 2, which used the susceptor of the reference example (the thickness of the upper plate being 0.5 mm), such camber was caused, and thus it was often observed that, in the susceptor, the wafer (substrate) was moved, however, with Example 1, which used the susceptor of Example (the thickness of the upper plate being 2 mm), there occurred no movement of the wafer. In other words, also from the viewpoint of avoidance of camber of the upper plate, a good result was obtained in the case where the susceptor of Example was used.

In addition, Table 2 gives evaluation results of having performed crystal growth, with the growth temperature having been set at 1300° C., and the pressure having been set at 10 Torr, using the susceptors of Example, the comparative example, and the reference example, and having evaluated the film thickness distribution and the crystallinity in the same manner as with the comparative example 1 and the reference example 1, under the headings of Example 2, comparative example 2, and reference example 3. From these results, it can be found that, although Example 2 and the reference example 3 exhibited a reduction in average growth rate, the values of film thickness distribution and crystallinity were decreased, as compared to those of the comparative example 2, the film thickness distribution and the crystallinity having been improved. In addition, in comparison of Example 2 with the reference example 3, it can be seen that Example 2 was provided with a larger effect of the improvement.

Even in the case where the susceptor of Example was used, cleaning of the AlN deposited on the upper plate was easy, and because the outer periphery projection part of the lower plate had a small area, even if AlN was deposited on the outer periphery projection part, the influence on the crystal growth on the substrate was small, whereby the cleaning frequency could be significantly reduced, as compared to that with the comparative example.

TABLE 2

| | | Comparative | Reference |
|---|---|---|---|
| | Example 2 | example 2 | example 3 |
| Growth temperature (° C.) | 1300 | 1300 | 1300 |
| Center film thickness (nm) | 597.7 | 600.2 | 588.5 |
| Average film thickness (nm) | 595 | 577.7 | 604.4 |
| Film thickness distribution (%) | 1.5 | 2.7 | 2.2 |
| Standardized growth speed | 0.909 | 1 | 0.936 |
| ΔXRC (002) | 14 | 49 | 15 |
| ΔXRC (102) | 178 | 382 | 292 |

In the above examples, the cases where AlN was grown have been described, however, also in the cases where AlGaN, GaN, and AlInGaN were grown, the same results were obtained. Thus, even in the case where the growth layer is of any other material, it is obvious that the same advantages will be provided, so long as there exists an influence of the growth temperature on the characteristics of the growth layer. For example, the growth layer is not limited to a semiconductor layer, and may be formed of any material. In addition, in the case where the growth layer is of a laminated structure of a plurality of layers, and the growth temperatures for the respective layers are the same or different from one another, if the above-described configuration gives the above-described effects to at least one of the layers, it is obvious that the above-described scheme is effective. In addition, in the above examples, the cases where the MOCVD method was used have been described, however, so long as the CVD method used is that which causes the material gas to react on the substrate at a high temperature, it is obvious that the same advantages can be obtained regardless of the type of gas.

### EXPLANATION OF SYMBOLS

The symbol 10, 20, 30, 90 denotes a susceptor; 11, 21, 31 a lower plate; 12, 22, 32 an upper plate; 50 a substrate; 91 a recessed part; 121, 221, 321 an opening part; 211, 311 a substrate mounting part; 312 an outer periphery projection part; 313 a lower plate top face (a top face of the lower plate); and 322 an upper plate bottom face (a bottom face of the upper plate)

1. A susceptor for holding a substrate, and forming a growth layer on the substrate by the chemical vapor deposition (CVD) method,
the susceptor comprising a lower plate and an upper plate, being disposed on a top face of the lower plate,
the lower plate including a substrate mounting part, the substrate mounting part being an area for mounting the substrate on the top face of the lower plate, and further, including an outer periphery projection part around the substrate mounting part, the outer periphery projection part being formed so as to provide a geometry, surrounding the substrate on the substrate mounting part,
the upper plate being mounted in an area excluding the substrate mounting part and the outer periphery projection part on the top face of the lower plate, and including a geometry, exposing the substrate mounting part and a top part of the outer periphery projection part on the side of a top face of the upper plate, and
a thermal conductivity in a vertical direction of the upper plate being lower than a thermal conductivity in a vertical direction of the lower plate.

2. The susceptor according to claim 1, wherein, in the substrate mounting part, the face, the substrate being mounted thereon, is set higher than the top face of the lower plate, the upper plate being mounted thereon, and is set such that, upon the lower plate being combined with the upper plate, the top face of the upper plate is flush with the top part of the outer periphery projection part.

3. The susceptor according to claim 1, wherein the width of the outer periphery projection part is in the range of 1.0 mm to 5.0 mm.

4. The susceptor according to claim 1, wherein the main material constituting the upper plate is pyrolithic graphite (pyrolytic carbon).

5. The susceptor according to claim 1, wherein a surface protection layer is provided on the surface of the lower plate.

6. The susceptor according to claim 5, wherein the surface protection layer is constituted by pyrolithic boron nitride (pBN) or silicon carbide (SiC).

7. A crystal growth apparatus, mounting a substrate on a susceptor,
and forming a growth layer on the substrate by the chemical vapor deposition method, the susceptor comprising a lower plate and an upper plate, being disposed on a top face of the lower plate,
the lower plate including a substrate mounting part, the substrate mounting part being an area for mounting the substrate on the top face of the lower plate, and further, including an outer periphery projection part around the substrate mounting part, the outer periphery projection part being formed so as to provide a geometry, surrounding the substrate on the substrate mounting part,
the upper plate being mounted in an area excluding the substrate mounting part and the outer periphery projection part on the top face of the lower plate, and including a geometry, exposing the substrate mounting part and a top part of the outer periphery projection part on the side of a top face of the upper plate, and
a thermal conductivity in a vertical direction of the upper plate being lower than a thermal conductivity in a vertical direction of the lower plate and a thermal conductivity in a vertical direction of the substrate, respectively.

8. The crystal growth apparatus according to claim 7, wherein, in the substrate mounting part, the face, the substrate being mounted thereon, is set higher than the top face of the lower plate, the upper plate being mounted thereon, and is set such that, upon the lower plate, the substrate, and the upper plate being combined with one another, the top face of the upper plate, the top face of the substrate, and the top part of the outer periphery projection part are flush with one another.

9. The crystal growth apparatus according to claim 7, wherein the width of the outer periphery projection part is in the range of 1.0 mm to 5.0 mm.

10. The crystal growth apparatus according to claim 7, wherein the main material constituting the lower plate is graphite, and the main material constituting the upper plate is pyrolithic graphite (pyrolytic carbon).

11. The crystal growth apparatus according to claim 7, wherein a surface protection layer is provided on the surface of the lower plate.

12. The crystal growth apparatus according to claim 11, wherein the surface protection layer is constituted by pyrolithic boron nitride (pBN) or silicon carbide (SiC).

13. A crystal growth method, using a crystal growth apparatus according to claim 7, comprising
heating the lower plate in a chamber, and with the substrate being mounted on the susceptor and heated, causing a material gas containing a raw material for the growth layer to flow.

14. The crystal growth method according to claim 13, wherein the substrate is of sapphire, and the temperature of the substrate at the time of growth of the growth layer is 1000° C. or over.

15. The crystal growth method according to claim 13, wherein the growth layer is of a nitride semiconductor.
